(19) United States
(12) Patent Application Publication
(10) Pub. No.: US 2026/0090233 A1
(43) Pub. Date: Mar. 26, 2026

(54) DISPLAY DEVICE, METHOD OF MANUFACTURING THE SAME, AND ELECTRONIC DEVICE INCLUDING THE SAME

(71) Applicant: Samsung Display Co., Ltd., Yongin-si (KR)

(72) Inventor: Young Jae JEON, Yongin-si (KR)

(21) Appl. No.: 19/175,994

(22) Filed: Apr. 10, 2025

(30) Foreign Application Priority Data
Sep. 25, 2024 (KR) 10-2024-0130121

(51) Int. Cl. H10K 59/80; H10K 59/12; H10K 59/122; H10K 59/131; H10K 102/00

(52) U.S. Cl. CPC H10K 59/80515; H10K 59/1201; H10K 59/122; H10K 59/131; H10K 2102/351

(57) ABSTRACT

A display device according to one or more embodiments of the present disclosure may include a substrate; first anode electrodes in first to third sub-pixel areas on the substrate and spaced from each other; second anode electrodes on the first anode electrodes, overlapping the first anode electrodes, and electrically connected to the first anode electrodes; a light emitting structure on the second anode electrodes; a cathode electrode on the light emitting structure; and transparent patterns between the first anode electrodes and the second anode electrodes, wherein a thickness of the transparent patterns in at least one of the first to third sub-pixel areas is different from thicknesses of the transparent patterns in other ones of the first to third sub-pixel areas.

### CROSS-REFERENCE TO RELATED APPLICATION

This application claims priority to and the benefit of Korean Patent Application No. 10-2024-0130121 filed on Sep. 25, 2024, in the Korean Intellectual Property Office, the entire disclosure of which is incorporated by reference herein.

### BACKGROUND

### 1. Field

The present disclosure relates to a display device, and more specifically, to a display device, a method of manufacturing the same, and an electronic device including the same.

### 2. Description of the Related Art

As information technology develops, the importance of a display device as a connection medium between a user and information is being emphasized. In response to this, the use of display devices such as a liquid crystal display device and an organic light emitting display device is increasing.

The above description is only for helping the understanding of the background art for the technical ideas of the present disclosure. Therefore, it should not be understood as the contents corresponding to the prior art known to those skilled in the art to which the present disclosure pertains.

### SUMMARY

Aspects and features of embodiments of the present disclosure are to provide a display device having uniformly improved luminance.

Other aspects and features of embodiments of the present disclosure are to provide a method of manufacturing the display device.

Aspects and features of embodiments of the present disclosure are not limited to the aspects and features mentioned above, and other technical aspects and features not mentioned will be clearly understood by those skilled in the art from the description below.

A display device according to one or more embodiments of the present disclosure may include a substrate; first anode electrodes in first to third sub-pixel areas on the substrate and spaced from each other; second anode electrodes on the first anode electrodes, overlapping the first anode electrodes, and electrically connected to the first anode electrodes; a light emitting structure on the second anode electrodes; a cathode electrode on the light emitting structure; and transparent patterns between the first anode electrodes and the second anode electrodes, wherein a thickness of the transparent patterns in at least one of the first to third sub-pixel areas is different from thicknesses of the transparent patterns in other ones of the first to third sub-pixel areas.

In one or more embodiments, the transparent patterns may be spaced from each other.

In one or more embodiments, the transparent patterns each overlapping the first to third sub-pixel areas may have different thicknesses.

In one or more embodiments, each of the first anode electrodes may be in direct contact with a corresponding one of the second anode electrodes.

In one or more embodiments, the display device may further include a pixel defining layer on the first anode electrodes and having openings overlapping the first anode electrodes.

In one or more embodiments, the transparent patterns may be within the openings, respectively.

In one or more embodiments, the second anode electrodes may overlap the openings, respectively.

In one or more embodiments, the pixel defining layer may have contact holes through which the first anode electrodes and the second anode electrodes are connected to each other, respectively.

In one or more embodiments, in each of the first to third sub-pixel areas, at least one of the openings and at least one of the contact holes may be located.

In one or more embodiments, each of the first anode electrodes may overlap the at least one of the openings and the contact hole in the pixel defining layer.

In one or more embodiments, each of the second anode electrodes may overlap the at least one of the openings and the contact hole in the pixel defining layer.

In one or more embodiments, each of the first anode electrodes may include at least one of silver or aluminum.

In one or more embodiments, each of the second anode electrodes may include a transparent conductive oxide.

In one or more embodiments, the transparent patterns may be conductive, and the first anode electrodes and the second anode electrodes may be electrically connected to each other through the transparent patterns.

A method of manufacturing a display device according to one or more embodiments of the present disclosure may include forming first anode electrodes located in first to third sub-pixel areas on a substrate and spaced from each other; forming second anode electrodes on the first anode electrodes, the second anode electrodes overlapping the first anode electrodes, and electrically connected to the first anode electrodes; forming a light emitting structure on the second anode electrodes; forming a cathode electrode on the light emitting structure; and forming transparent patterns between the first anode electrodes and the second anode electrodes, a thickness of the transparent patterns in at least one of the first to third sub-pixel areas being different from thicknesses of the transparent patterns in other ones of the first to third sub-pixel areas.

In one or more embodiments, the transparent patterns may be formed by an inkjet process.

In one or more embodiments, the transparent patterns overlapping the first to third sub-pixel areas may have different thicknesses.

In one or more embodiments, the method of manufacturing the display device may further include forming a pixel defining layer on the first anode electrodes before the forming the second anode electrodes.

In one or more embodiments, the forming the pixel defining layer may include forming openings overlapping the first anode electrodes and contact holes each overlapping the first anode electrodes and spaced from the openings.

In one or more embodiments, the transparent patterns may be formed of a conductive material, and only the openings in which the transparent patterns are disposed may be formed in the pixel defining layer.

An electronic device includes a processor to provide input image data; and a display device to display an image based on the input image data, wherein the display device includes: a substrate; first anode electrodes in first to third sub-pixel areas on the substrate and spaced from each other; second anode electrodes on the first anode electrodes, overlapping the first anode electrodes, and electrically connected to the first anode electrodes; a light emitting structure on the second anode electrodes; a cathode electrode on the light emitting structure; and transparent patterns between the first anode electrodes and the second anode electrodes, wherein a thickness of the transparent patterns in at least one of the first to third sub-pixel areas is different from thicknesses of the transparent patterns in other ones of the first to third sub-pixel areas.

Other specific details of embodiments are included in the detailed description and accompanying drawings.

### BRIEF DESCRIPTION OF THE DRAWINGS

The accompanying drawings, which are included to provide a further understanding of the present disclosure, and are incorporated in and constitute a part of this specification, illustrate example embodiments of the present disclosure, and, together with the description, serve to explain principles and scope of the present disclosure.

FIG. 1 is a block diagram illustrating an embodiment of a display device according to one or more embodiments.

FIG. 2 is a block diagram illustrating an embodiment of one of sub-pixels of FIG. 1.

FIG. 3 is a circuit diagram illustrating an embodiment of the sub-pixel of FIG. 2.

FIG. 4 is a plan view illustrating an embodiment of a display panel of FIG. 1.

FIG. 5 is a cross-sectional view illustrating an embodiment of the display panel of FIG. 4.

FIG. 6 is a cross-sectional view illustrating another embodiment of the display panel of FIG. 4.

FIG. 7 is a plan view illustrating an embodiment of one of the pixels of FIG. 4.

FIG. 8 is a cross-sectional view taken along the line I-I′ in FIG. 7.

FIG. 9 is a plan view illustrating an embodiment of another one of the pixels of FIG. 4.

FIG. 10 is a cross-sectional view taken along the line II-II′ in FIG. 9.

FIG. 11 is a cross-sectional view illustrating an embodiment of a portion of a light emitting structure included in one of first to third light emitting elements of FIG. 8 or FIG. 10.

FIG. 12 is a cross-sectional view illustrating another embodiment of a portion of the light emitting structure included in one of the first to third light emitting elements of FIG. 8 or FIG. 10.

FIG. 13 is a plan view illustrating another embodiment of one of the pixels of FIG. 4.

FIG. 14 is a plan view illustrating still another embodiment of one of the pixels of FIG. 4.

FIGS. 15-21 are diagrams illustrating a method of manufacturing a display device according to one or more embodiments of the present disclosure.

FIG. 22 is a block diagram of an electronic device according to one or more embodiments.

FIG. 23 shows schematic views of various embodiments of an electronic device.

### DETAILED DESCRIPTION

Hereinafter, embodiments of the present disclosure will be described in more detail with reference to the accompanying drawings. It should be noted that in the following description, only the parts necessary to understand the operation according to the present disclosure will be described, and descriptions of other parts will be omitted in order to not obscure the gist of the present disclosure. In addition, the present disclosure is not limited to embodiments described herein and may be embodied in other forms. Embodiments described herein are provided merely to explain in detail sufficient to enable those skilled in the art to implement the technical idea of the present disclosure without undue experimentation.

Throughout the specification, in a case where a portion is “connected” to another portion, the case includes not only a case where the portion is “directly connected” but also a case where the portion is “indirectly connected” with another element interposed therebetween. Terms used herein are for describing specific embodiments and are not intended to limit the present disclosure. Throughout the specification, in a case where a certain portion “includes”, the case means that the portion may further include another component without excluding another component unless otherwise stated. “At least one of X, Y, and Z”, “at least one of X, Y, or Z,” and “at least one selected from a group consisting of X, Y, and Z” may be interpreted as one X, one Y, one Z, or any combination of two or more of X, Y, and Z (for example, XYZ, XYY, YZ, and ZZ). Here, “and/or” includes all combinations of one or more of corresponding configurations.

Here, terms such as first and second may be used to describe various components, but these components are not limited to these terms. These terms are used to distinguish one component from another component. Therefore, a first component may refer to a second component within a range without departing from the scope disclosed herein.

Spatially relative terms such as “under”, “on”, and/or the like may be used for descriptive purposes, thereby describing the relationship between one element or feature and another element(s) or feature(s) as shown in the drawings. Spatially relative terms are intended to include other directions in use, in operation, and/or in manufacturing, in addition to the direction depicted in the drawings. For example, when a device shown in the drawing is turned upside down, elements depicted as being positioned “under” other elements or features are positioned in a direction “on” the other elements or features. Therefore, in one or more embodiments, the term “under” may include both directions of on and under. In addition, the device may face in other directions (for example, rotated 90 degrees or in other directions) and thus the spatially relative terms used herein are interpreted according thereto.

Various embodiments are described with reference to drawings schematically illustrating ideal embodiments. Accordingly, it will be expected that shapes may vary, for example, according to tolerances and/or manufacturing techniques. Therefore, the embodiments disclosed herein cannot be construed as being limited to shown specific shapes, and should be interpreted as including, for example, changes in shapes that occur as a result of manufacturing. As described above, the shapes shown in the drawings may not show actual shapes of areas of a device, and the present embodiments are not limited thereto.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

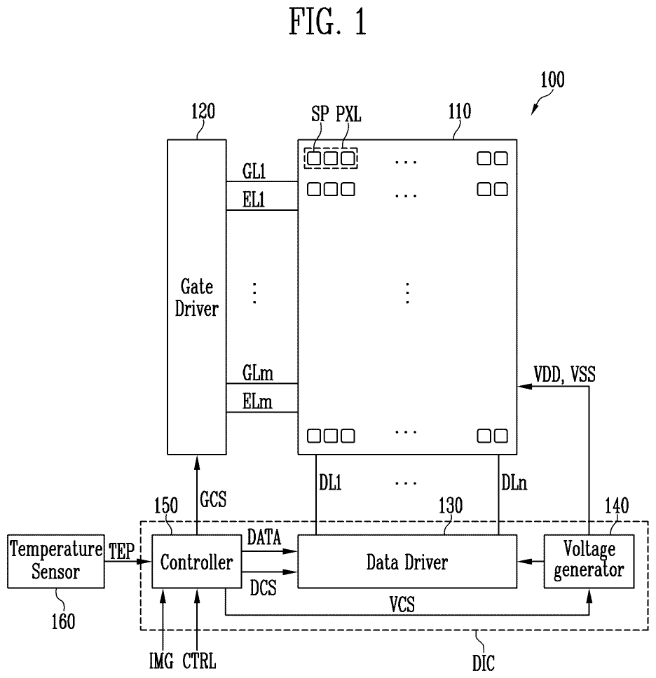

FIG. 1 is a block diagram illustrating an embodiment of a display device according to one or more embodiments.

Referring to FIG. 1, a display device 100 may include a display panel 110, a gate driver 120, a data driver 130, a voltage generator 140, a controller 150, and a temperature sensor 160.

The display panel 110 may include sub-pixels SP. The sub-pixels SP may be connected to the gate driver 120 through first to m-th gate lines GL1 to GLm. The sub-pixels SP may be connected to the data driver 130 through first to n-th data lines DL1 to DLn.

Each of the sub-pixels SP may include at least one light emitting element configured to generate light. Accordingly, each of the sub-pixels SP may generate light of a specific color, such as red, green, blue, cyan, magenta, or yellow. Two or more sub-pixels from among the sub-pixels SP may constitute one pixel PXL. For example, as shown in FIG. 1, three sub-pixels may constitute one pixel PXL.

The gate driver 120 may be connected to the sub-pixels SP arranged in a row direction through the first to m-th gate lines GL1 to GLm. The gate driver 120 may output gate signals to the first to m-th gate lines GL1 to GLm in response to a gate control signal GCS from the controller 150. In one or more embodiments, the gate control signal GCS may include a start signal indicating the start of each frame, a horizontal synchronization signal for outputting gate signals in synchronization with the timing at which data signals are applied, and/or the like.

In one or more embodiments, first to m-th emission control lines EL1 to ELm connected to the sub-pixels SP arranged in the row direction may be further provided. In this case, the gate driver 120 may include an emission control driver configured to control the first to m-th emission control lines EL1 to ELm, and the emission control driver may operate under the control of the controller 150.

The gate driver 120 may be disposed on one side of the display panel 110. However, the present disclosure is not limited thereto. For example, the gate driver 120 may be divided into two or more drivers that are physically and/or logically separated. Such drivers may be disposed on one side of the display panel 110 and the other side of the display panel 110 opposite to the one side. In this way, the gate driver 120 may be disposed on the periphery of the display panel 110 in various forms according to one or more embodiments.

The data driver 130 may be connected to the sub-pixels SP arranged in a column direction through the first to n-th data lines DL1 to DLn. The data driver 130 may receive image data DATA and a data control signal DCS from the controller 150. The data driver 130 may operate in response to the data control signal DCS. In one or more embodiments, the data control signal DCS may include a source start pulse, a source shift clock, a source output enable signal, and/or the like.

The data driver 130 may apply data signals having grayscale voltages corresponding to the image data DATA to the first to n-th data lines DL1 to DLn using voltages from the voltage generator 140. When a gate signal is applied to each of the first to m-th gate lines GL1 to GLm, data signals corresponding to the image data DATA may be applied to the data lines DL1 to DLn. Accordingly, corresponding sub-pixels SP may generate light corresponding to the data signals. Accordingly, an image may be displayed on the display panel 110.

In one or more embodiments, the gate driver 120 and data driver 130 may include complementary metal-oxide semiconductor (CMOS) circuit elements.

The voltage generator 140 may operate in response to a voltage control signal VCS from the controller 150. The voltage generator 140 may be configured to generate a plurality of voltages and provide the generated voltages to components of the display device 100. For example, the voltage generator 140 may be configured to generate the plurality of voltages by receiving an input voltage from outside the display device 100, adjusting the received voltage, and regulating the adjusted voltage.

The voltage generator 140 may generate a first power source voltage VDD and a second power source voltage VSS, and the generated first and second power source voltages VDD and VSS may be provided to the sub-pixels SP. The first power source voltage VDD may have a relatively high voltage level, and the second power source voltage VSS may have a lower voltage level than the first power source voltage VDD. In one or more embodiments, the first power source voltage VDD or the second power source voltage VSS may be provided by a device external to the display device 100.

In addition, the voltage generator 140 may generate various voltages. For example, the voltage generator 140 may generate an initialization voltage applied to the sub-pixels SP. For example, during a sensing operation for sensing electrical characteristics of transistors and/or light emitting elements of the sub-pixels SP, a suitable reference voltage (e.g., a predetermined reference voltage) may be applied to the first to n-th data lines DL1 to DLn, and the voltage generator 140 may generate the reference voltage.

The controller 150 may control all operations of the display device 100. The controller 150 may receive input image data IMG and a control signal CTRL for controlling its display from the outside. In response to the control signal CTRL, the controller 150 may provide the gate control signal GCS, the data control signal DCS, and the voltage control signal VCS.

The controller 150 may convert the input image data IMG to be suitable for the display device 100 or the display panel 110 and output the image data DATA. In one or more embodiments, the controller 150 may arrange the input image data IMG to be suitable for the sub-pixels SP in a row unit to output the image data DATA.

Two or more components of the data driver 130, the voltage generator 140, and the controller 150 may be mounted on a single integrated circuit (IC). As shown in FIG. 1, the data driver 130, the voltage generator 140, and the controller 150 may be included in a driver integrated circuit DIC. In such a case, the data driver 130, the voltage generator 140, and the controller 150 may be functionally separate components within a single driver integrated circuit DIC. In one or more embodiments, at least one of the data driver 130, the voltage generator 140, or the controller 150 may be provided as a separate component from the driver integrated circuit DIC.

The display device 100 may include at least one temperature sensor 160. The temperature sensor 160 may be configured to sense the temperature of its surroundings and generate temperature data TEP representing the sensed temperature. In one or more embodiments, the temperature sensor 160 may be disposed adjacent to the display panel 110 and/or the driver integrated circuit DIC.

The controller 150 may control various operations of the display device 100 in response to the temperature data TEP. In one or more embodiments, the controller 150 may adjust the luminance of an image output from the display panel 110 in response to the temperature data TEP. For example, the controller 150 may adjust the data signals and the first and second power source voltages VDD and VSS by controlling components such as the data driver 130 and/or the voltage generator 140.

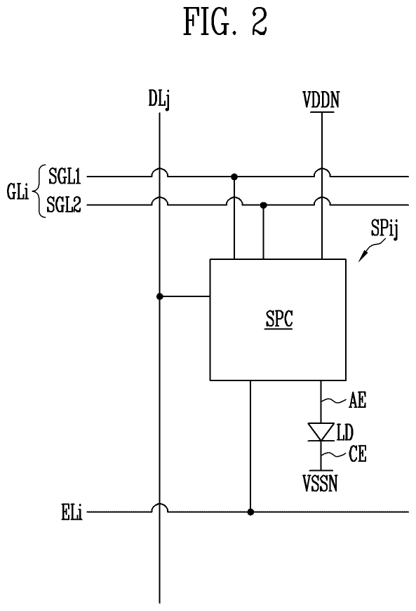

FIG. 2 is a block diagram illustrating an embodiment of one of sub-pixels of FIG. 1. FIG. 2 shows, as an example, a sub-pixel SPij arranged in an i-th row (i may be an integer greater than or equal to 1 and less than or equal to m) and a j-th column (j may be an integer greater than or equal to 1 and less than or equal to n) from among the sub-pixels SP of FIG. 1.

Referring to FIG. 2, the sub-pixel SPij may include a sub-pixel circuit SPC and a light emitting element LD.

The light emitting element LD may be connected between a first power source voltage node VDDN and a second power source voltage node VSSN. In this case, the first power source voltage node VDDN may be a node that transmits the first power source voltage VDD of FIG. 1, and the second power source voltage node VSSN may be a node that transmits the second power source voltage VSS of FIG. 1.

An anode electrode AE of the light emitting element LD may be connected to the first power source voltage node VDDN through the sub-pixel circuit SPC, and a cathode electrode CE of the light emitting element LD may be connected to the second power source voltage node VSSN. For example, the anode electrode AE of the light emitting element LD may be connected to the first power source voltage node VDDN through one or more transistors included in the sub-pixel circuit SPC.

The sub-pixel circuit SPC may be connected to an i-th gate line GLi from among the first to m-th gate lines GL1 to GLm of FIG. 1, an i-th emission control line ELi from among the first to m-th emission control lines EL1 to ELm of FIG. 1, and a j-th data line DLj from among the first to n-th data lines DL1 to DLn of FIG. 1. The sub-pixel circuit SPC may be configured to control the light emitting element LD according to signals received through these signal lines.

The sub-pixel circuit SPC may operate in response to a gate signal received through the i-th gate line GLi. The i-th gate line GLi may include one or more sub-gate lines. In one or more embodiments, as shown in FIG. 2, the i-th gate line GLi may include first and second sub-gate lines SGL1 and SGL2. The sub-pixel circuit SPC may operate in response to gate signals received through the first and second sub-gate lines SGL1 and SGL2. In this way, when the i-th gate line GLi includes two or more sub-gate lines, the sub-pixel circuit SPC may operate in response to gate signals received through corresponding sub-gate lines.

The sub-pixel circuit SPC may operate in response to an emission control signal received through the i-th emission control line ELi. In one or more embodiments, the i-th emission control line ELi may include one or more sub-emission control lines. When the i-th emission control line ELi includes two or more sub-emission control lines, the sub-pixel circuit SPC may operate in response to emission control signals received through corresponding sub-emission control lines.

The sub-pixel circuit SPC may receive a data signal through the j-th data line DLj. The sub-pixel circuit SPC may store a voltage corresponding to the data signal in response to at least one of the gate signals received through the first and second sub-gate lines SGL1 and SGL2. In response to the emission control signal received through the i-th emission control line Eli, the sub-pixel circuit SPC may control the current flowing from the first power source voltage node VDDN to the second power source voltage node VSSN through the light emitting element LD according to the stored voltage. Accordingly, the light emitting element LD may generate light with a luminance corresponding to the data signal.

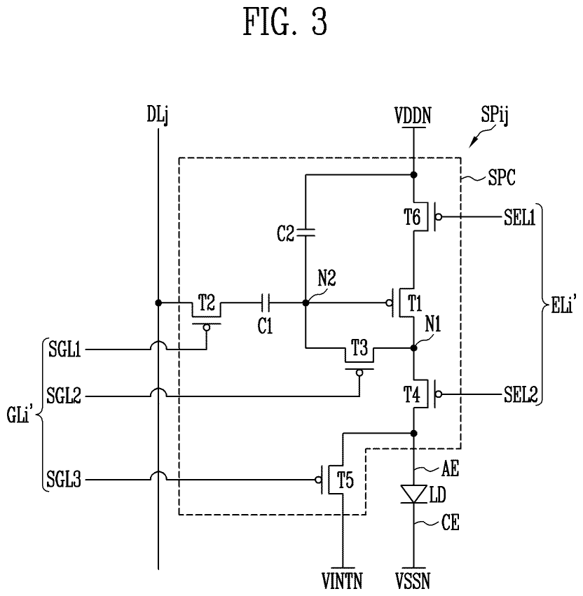

FIG. 3 is a circuit diagram illustrating an embodiment of the sub-pixel of FIG. 2.

Referring to FIG. 3, a sub-pixel SPij may include a sub-pixel circuit SPC and a light emitting element LD.

The sub-pixel circuit SPC may be connected to an i-th gate line GLi′, an i-th emission control line ELi′, and a j-th data line DLj. Compared with the i-th gate line GLi of FIG. 2, the i-th gate line GLi′ may further include a third sub-gate line SGL3. Compared with the i-th emission control line ELi of FIG. 2, the i-th emission control line ELi′ may include a first sub-emission control line SEL1 and a second sub-emission control line SEL2.

The sub-pixel circuit SPC may include first to sixth transistors T1 to T6, and first and second capacitors C1 and C2.

The first transistor T1 may be connected between a first power source voltage node VDDN and a first node N1. A gate of the first transistor T1 may be connected to a second node N2, and thus, the first transistor T1 may be turned on according to a voltage level of the second node N2. The first transistor T1 may be referred to as a driving transistor.

The second transistor T2 may be connected between the j-th data line DLj and the second node N2. A gate of the second transistor T2 may be connected to the first sub-gate line SGL1, and thus, the second transistor T2 may be turned on in response to a gate signal of the first sub-gate line SGL1. The second transistor T2 may be referred to as a switching transistor.

The third transistor T3 may be connected between the first node N1 and the second node N2. A gate of the third transistor T3 may be connected to the second sub-gate line SGL2, and thus, the third transistor T3 may be turned on in response to a gate signal of the second sub-gate line SGL2 to diode connect the first transistor T1.

The fourth transistor T4 may be connected between the first node N1 and an anode electrode AE of the light emitting element LD. A gate of the fourth transistor T4 may be connected to the second sub-emission control line SEL2, and thus the fourth transistor T4 may be turned on in response to an emission control signal of the second sub-emission control line SEL2.

The fifth transistor T5 may be connected between the anode electrode AE of the light emitting element LD and an initialization voltage node VINTN. The initialization voltage node VINTN may be configured to transmit an initialization voltage. In one or more embodiments, the initialization voltage may be provided by the voltage generator 140 of FIG. 1. In one or more embodiments, the initialization voltage may be provided by a device external to the display device 100. A gate of the fifth transistor T5 may be connected to the third sub-gate line SGL3, and thus the fifth transistor T5 may be turned on in response to a gate signal of the third sub-gate line SGL3.

The sixth transistor T6 may be connected between the first power source voltage node VDDN and the first transistor T1. A gate of the sixth transistor T6 may be connected to the first sub-emission control line SEL1, and thus the sixth transistor T6 may be turned on in response to an emission control signal of the first sub-emission control line SEL1.

The first capacitor C1 may be connected between the second transistor T2 and the second node N2. The second capacitor C2 may be connected between the first power source voltage node VDDN and the second node N2.

As such, the sub-pixel circuit SPC may include the first to sixth transistors T1 to T6, and the first and second capacitors C1 and C2. However, the present disclosure is not limited thereto. The sub-pixel circuit SPC may be implemented as one of various types of circuits including a plurality of transistors and one or more capacitors. For example, the sub-pixel circuit SPC may include two transistors and one capacitor. According to one or more embodiments of the sub-pixel circuit SPC, the number of sub-gate lines included in the i-th gate line GLi′ and the number of sub-emission control lines included in the i-th emission control line ELi′ may vary.

The first to sixth transistors T1 to T6 may be P-type transistors. Each of the first to sixth transistors T1 to T6 may be a Metal Oxide Silicon Field Effect Transistor (MOSFET). However, the present disclosure is not limited thereto. For example, at least one of the first to sixth transistors T1 to T6 may be replaced with an N-type transistor.

In one or more embodiments, the first to sixth transistors T1 to T6 may include an amorphous silicon semiconductor, a monocrystalline silicon semiconductor, a polycrystalline silicon semiconductor, an oxide semiconductor, and/or the like.

The light emitting element LD may include the anode electrode AE, the cathode electrode CE, and a light emitting layer. The light emitting layer may be disposed between the anode electrode AE and the cathode electrode CE. After the data signal transmitted through the j-th data line DLj is reflected in a voltage of the second node N2, the fourth and sixth transistors T4 and T6 may be turned on when emission control signals of the first and second sub-emission control lines SEL1 and SEL2 are enabled to a low level. In addition, the first transistor T1 may be turned on according to the voltage of the second node N2, and thus the current may flow from the first power source voltage node VDDN to the second power source voltage node VSSN. The light emitting element LD may emit light according to the amount of current flowing.

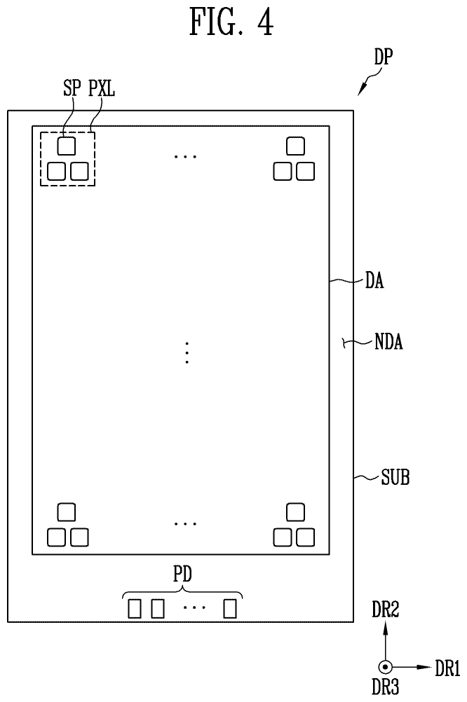

FIG. 4 is a plan view illustrating an embodiment of a display panel of FIG. 1.

Referring to FIG. 4, an embodiment DP of the display panel 110 of FIG. 1 may include a display area DA and a non-display area NDA along an edge or a periphery of the display area DA. The display panel DP may display an image through the display area DA. The non-display area NDA may be disposed around the display area DA.

The display panel DP may include a substrate SUB, sub-pixels SP, and pads PD.

When the display panel DP is used as a display screen for a head-mounted display (HMD) device, a virtual reality (VR) device, a mixed reality (MR) device, an augmented reality (AR) device, and/or the like, the display panel DP may be positioned very close to the user's eyes. In such cases, sub-pixels SP with relatively high integration may be required. To increase the integration of the sub-pixels SP, the substrate SUB may be provided as a silicon substrate. The sub-pixels SP and/or the display panel DP may be formed on the substrate SUB, which is a silicon substrate. The display device 100 (see FIG. 1) including the display panel DP formed on the substrate SUB, which is a silicon substrate, may be referred to as an OLEDOS (OLED on Silicon) display device.

The sub-pixels SP may be disposed in the display area DA on the substrate SUB. The sub-pixels SP may be arranged in a matrix form along a first direction DR1 and a second direction DR2 intersecting the first direction DR1. However, the present disclosure is not limited thereto. For example, the sub-pixels SP may be arranged in a zigzag shape along the first direction DR1 and the second direction DR2. For example, the sub-pixels SP may be arranged in a PENTILE® shape. The PENTILE® pixel arrangement structure may be referred to as an RGBG matrix structure (e.g., a PENTILE® matrix structure or an RGBG structure (e.g., a PENTILE® structure)). PENTILE® is a registered trademark of Samsung Display Co., Ltd., Republic of Korea. The first direction DR1 may be a row direction, and the second direction DR2 may be a column direction.

Two or more sub-pixels from among a plurality of sub-pixels SP may constitute one pixel PXL.

Components for controlling the sub-pixels SP may be disposed in the non-display area NDA of the substrate SUB. For example, wirings connected to the sub-pixels SP, such as the first to m-th gate lines GL1 to GLm and the first to n-th data lines DL1 to DLn of FIG. 1, may be disposed in the non-display area NDA.

At least one of the gate driver 120, the data driver 130, the voltage generator 140, the controller 150, or the temperature sensor 160 of FIG. 1 may be integrated in a non-display area NDA of the display panel DP. In one or more embodiments, the gate driver 120 of FIG. 1 may be mounted on the display panel DP and disposed in the non-display area NDA. In one or more embodiments, the gate driver 120 may be implemented as an integrated circuit (IC) separate from the display panel DP. In one or more embodiments, the temperature sensor 160 may be disposed in the non-display area NDA to sense the temperature of the display panel DP.

The pads PD may be disposed in the non-display area NDA on the substrate SUB. The pads PD may be electrically connected to the sub-pixels SP through wirings. For example, the pads PD may be connected to the sub-pixels SP through the first to n-th data lines DL1 to DLn.

The pads PD may interface the display panel DP to other components of the display device 100 (see FIG. 1). In one or more embodiments, voltages and signals necessary to operate the components included in the display panel DP may be provided from the driver integrated circuit DIC of FIG. 1 through the pads PD. For example, the first to n-th data lines DL1 to DLn may be connected to the driver integrated circuit DIC through the pads PD. For example, the first and second power source voltages VDD and VSS may be received from the driver integrated circuit DIC through the pads PD. For example, when the gate driver 120 is mounted on the display panel DP, the gate control signal GCS may be transmitted from the driver integrated circuit DIC to the gate driver 120 through the pads PD.

In one or more embodiments, a circuit board may be electrically connected to the pads PD by a conductive adhesive such as an anisotropic conductive film. In this case, the circuit board may be a flexible circuit board (FPCB) or a flexible film having a flexible material. The driver integrated circuit DIC may be mounted on the circuit board and electrically connected to the pads PD.

In one or more embodiments, the display area DA may have various shapes. The display area DA may have a closed loop shape including straight and/or curved sides. For example, the display area DA may have a shape such as a polygon, a circle, a semicircle, or an ellipse.

In one or more embodiments, the display panel DP may have a flat display surface. In one or more embodiments, the display panel DP may have an at least partially rounded display surface. In one or more embodiments, the display panel DP may be bent, folded, and/or rolled. In these cases, the display panel DP and/or the substrate SUB may include a material having flexible properties.

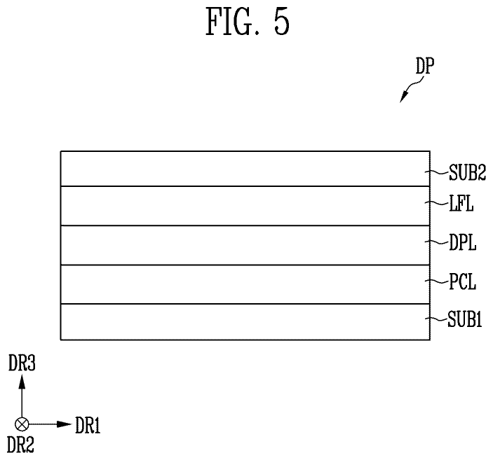

FIG. 5 is a cross-sectional view illustrating an embodiment of the display panel of FIG. 4.

Referring to FIG. 5, a display panel DP may include a first substrate SUB1, and a pixel circuit layer PCL, a display element layer DPL, a light functional layer LFL, and a second substrate SUB2 that are sequentially laminated in a third direction DR3 intersecting the first and second directions DR1 and DR2 on the first substrate SUB1.

The first substrate SUB1 may be made of an insulating material such as glass and/or resin. For example, the first substrate SUB1 may include a glass substrate. As another example, the first substrate SUB1 may include a PI (Polyimide) substrate. As still another example, the first substrate SUB1 may include a silicon wafer substrate formed using a semiconductor process.

In one or more embodiments, the first substrate SUB1 may be made of a flexible material that can be bent and/or folded, and may have a single-layer structure or a multi-layer structure. For example, the flexible material may include polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, and/or cellulose acetate propionate. However, the present disclosure is not limited thereto.

The pixel circuit layer PCL may be disposed on the first substrate SUB1. The pixel circuit layer PCL may include insulating layers, and semiconductor patterns and conductive patterns disposed between the insulating layers. The conductive patterns of the pixel circuit layer PCL may function as circuit elements, wirings, and/or the like.

The circuit elements of the pixel circuit layer PCL may include the sub-pixel circuit SPC (see FIG. 2) of each of the sub-pixels SP of FIG. 3. In other words, the circuit elements of the pixel circuit layer PCL may be provided as transistors and one or more capacitors of the sub-pixel circuit SPC.

The wirings of the pixel circuit layer PCL may include wirings connected to the sub-pixels SP. The wirings of the pixel circuit layer PCL may include various signal lines and/or voltage lines necessary to drive the display element layer DPL.

The display element layer DPL may be disposed on the pixel circuit layer PCL. The display element layer DPL may include light emitting elements of the sub-pixels SP.

The light functional layer LFL may be disposed on the display element layer DPL. The light functional layer LFL may include light conversion patterns having color conversion particles and/or scattering particles. For example, the color conversion particles may include quantum dots. The quantum dots may change the wavelength (or color) of light emitted from the display element layer DPL. The light functional layer LFL may further include light scattering patterns having scattering particles. In one or more embodiments, the light conversion patterns and the light scattering patterns may be omitted.

The light functional layer LFL may further include a color filter layer including color filters. The color filters may selectively transmit light of a specific wavelength (or a specific color). In one or more embodiments, the color filter layer may be omitted.

The second substrate SUB2 may be provided on the light functional layer LFL to protect an exposed surface (or upper surface) of the display panel DP. The second substrate SUB2 may protect the display panel DP from external impact. The second substrate SUB2, like the first substrate SUB1, may be made of an insulating material such as glass and/or resin. For example, the second substrate SUB2 may include a glass substrate.

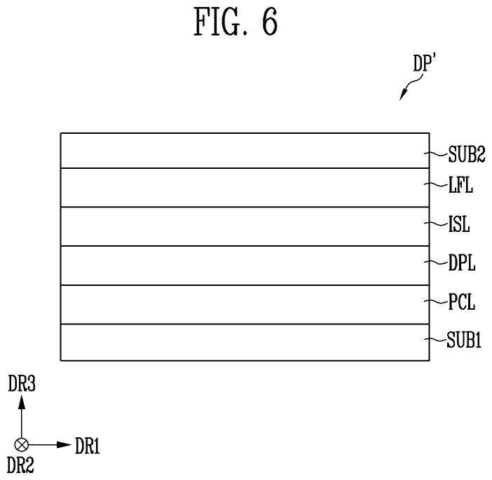

FIG. 6 is a cross-sectional view illustrating another embodiment of the display panel of FIG. 4.

Referring to FIG. 6, a display panel DP′ may include a first substrate SUB1, a pixel circuit layer PCL, a display element layer DPL, an input sensing layer ISL, a light functional layer LFL, and a second substrate SUB2. The first substrate SUB1, the pixel circuit layer PCL, the display element layer DPL, the light functional layer LFL, and the second substrate SUB2 may be configured similarly to the first substrate SUB1, the pixel circuit layer PCL, the display element layer DPL, the light functional layer LFL, and the second substrate SUB2 described with reference to FIG. 5. Hereinafter, duplicate descriptions will be omitted.

The input sensing layer ISL may detect a user's input on an upper surface (or display surface) of the display panel DP′. The input sensing layer ISL may include components suitable for detecting an external object such as a user's hand, a pen, and/or the like. For example, the input sensing layer ISL may include touch electrodes.

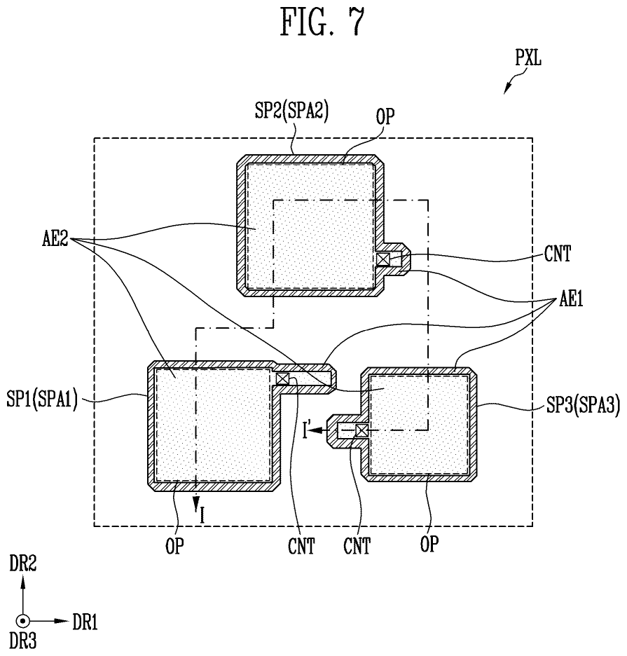

FIG. 7 is a plan view illustrating an embodiment of one of pixels of FIG. 4.

Referring to FIG. 7, a pixel PXL may include first to third sub-pixels SP1 to SP3. The first and third sub-pixels SP1 and SP3 may be arranged along the first direction DR1. The second sub-pixel SP2 may be arranged in a direction inclined at an acute angle (or diagonal direction) with respect to the first sub-pixel SP1 based on the second direction DR2. The first to third sub-pixels SP1 to SP3 may be arranged in first to third sub-pixel areas SPA1 to SPA3, respectively.

Each of the first to third sub-pixels SP1 to SP3 may include a first anode electrode AE1 and a second anode electrode AE2. That is, first anode electrodes AE1 may be disposed in the first to third sub-pixel areas SPA1 to SPA3, respectively, and second anode electrodes AE2 may also be disposed in the first to third sub-pixel areas SPA1 to SPA3, respectively.

The first anode electrodes AE1 may be spaced (e.g., spaced apart) from each other. The second anode electrodes AE2 may be disposed on the first anode electrode AE1, respectively, and may entirely overlap the first anode electrodes AE1. In addition, the second anode electrodes AE2 may be electrically connected to the first anode electrodes AE1, respectively. Like the first anode electrodes AE1, the second anode electrodes AE2 may be spaced (e.g., spaced apart) from each other.

At least one contact hole CNT may be defined in each of the first to third sub-pixel areas SPA1 to SPA3. The contact holes CNT may connect the first anode electrodes AE1 and the second anode electrodes AE2 to each other.

At least one opening OP may be defined in each of the first to third sub-pixel areas SPA1 to SPA3. The openings OP may be spaced (e.g., spaced apart) from the contact holes CNT on a plane (e.g., in a plan view).

The openings OP may overlap the first anode electrodes AE1, respectively. Because the second anode electrodes AE2 overlap the first anode electrodes AE1, the openings OP may also overlap the second anode electrodes AE2, respectively.

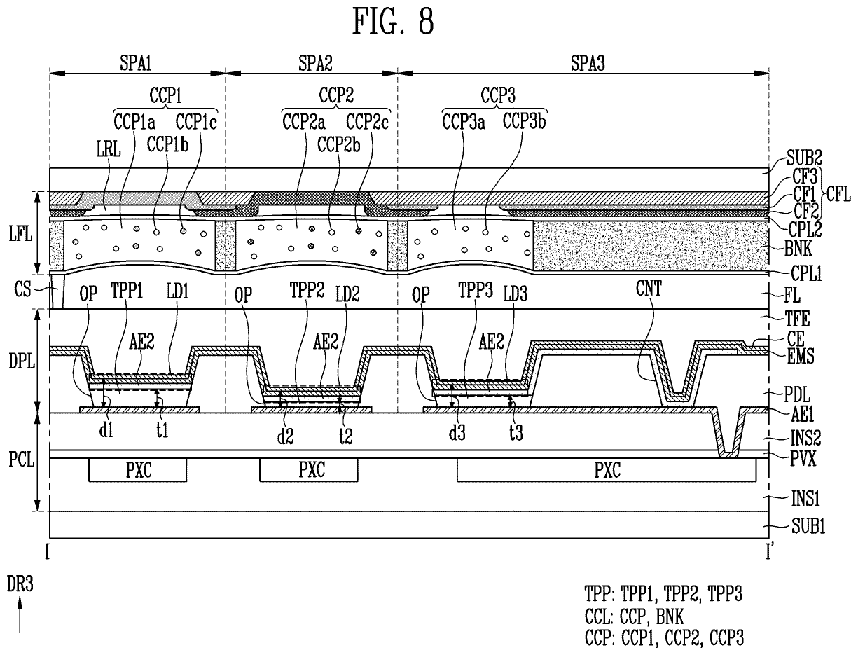

A pixel defining layer PDL (see FIG. 8) may be disposed between the first anode electrodes AE1 and the second anode electrodes AE2. The pixel defining layer PDL may define the openings OP and the contact holes CNT. Accordingly, each of the first anode electrodes AE1 may overlap at least one opening OP and at least one contact hole CNT under the pixel defining layer PDL. In addition, each of the second anode electrodes AE2 may overlap at least one opening OP and at least one contact hole CNT on the pixel defining layer PDL.

FIG. 8 is a cross-sectional view taken along the line I-I′ in FIG. 7.

Referring to FIG. 8, the pixel circuit layer PCL may be disposed on the first substrate SUB1. The pixel circuit layer PCL may include circuit elements PXC, a first insulating layer INS1, a passivation layer PVX, and a second insulating layer INS2.

The first insulating layer INS1 and the circuit elements PXC may be disposed on the first substrate SUB1. The circuit elements PXC may be included in each of the first to third sub-pixels SP1 to SP3 and may be disposed in each of the first to third sub-pixel areas SPA1 to SPA3. Each of the circuit elements PXC may be provided as transistors and capacitors of each of the sub-pixels.

The passivation layer PVX may be disposed on the first insulating layer INS1 and the circuit elements PXC. The passivation layer PVX may extend entirely over the pixel circuit layer PCL. The second insulating layer INS2 may be disposed on the passivation layer PVX. In this case, the second insulating layer INS2 may include an organic material. However, the present disclosure is not limited thereto.

The display element layer DPL may be disposed on the second insulating layer INS2. The display element layer DPL may include first anode electrodes AE1, transparent patterns TPP, second anode electrodes AE2, a pixel defining layer PDL, a light emitting structure EMS, and a cathode electrode CE.

The first anode electrodes AE1 may be disposed on the second insulating layer INS2. The first anode electrodes AE1 may be connected to corresponding circuit elements PXC, respectively. That is, the first anode electrodes AE1 and the circuit elements PXC disposed in the first to third sub-pixel areas SPA1 to SPA3 may correspond to each other and may be connected to each other through holes defined in the second insulating layer INS2 and the passivation layer PVX.

The first anode electrodes AE1 may include a metal having high reflectivity. The first anode electrodes AE1 may include silver and/or aluminum. For example, each of the first anode electrodes AE1 may have a structure in which indium tin oxide, silver, and/or indium tin oxide are laminated.

The pixel defining layer PDL may be disposed on the first anode electrodes AE1. The pixel defining layer PDL may define the openings OP that overlap the first anode electrodes AE1. That is, the openings OP may partially expose upper surfaces of the first anode electrodes AE1. As the pixel defining layer PDL defines the openings OP that partially overlap the first anode electrodes AE1, the pixel defining layer PDL may cover edges of the first anode electrodes AE1.

In addition, the pixel defining layer PDL may define the contact holes CNT that are spaced (e.g., spaced apart) from the openings OP and overlap the first anode electrodes AE1. That is, one first anode electrode AE1 disposed in each of the first to third sub-pixel areas SPA1 to SPA3 may overlap one opening OP and one contact hole CNT.

The second anode electrodes AE2 may be disposed on the first anode electrodes AE1 and the pixel defining layer PDL. The second anode electrodes AE2 may overlap the first anode electrodes AE1 and may be electrically connected to the first anode electrodes AE1, respectively.

The first anode electrodes AE1 and the second anode electrodes AE2 that overlap each other may be electrically connected to each other through the contact holes CNT. Specifically, each of the first anode electrodes AE1 may directly contact each of the second anode electrodes AE2 through a contact hole CNT. The second anode electrodes AE2 may be electrically connected to the first anode electrodes AE1, so that signals may be received from the first anode electrodes AE1 connected to the circuit elements PXC.

The second anode electrodes AE2 may include a transparent conductive oxide. For example, the second anode electrodes AE2 may include indium tin oxide. That is, the second anode electrodes AE2 may be composed of a material having high transmittance and may transmit light. Because the first anode electrodes AE1 are composed of a material having high reflectivity and the second anode electrodes AE2 are composed of a material having high transmittance, light generated in the light emitting structure EMS may be reflected by the first anode electrodes AE1 and then transmitted through the second anode electrodes AE2 to be emitted to the front.

The transparent patterns TPP may be disposed between the first anode electrodes AE1 and the second anode electrodes AE2. That is, the transparent patterns TPP may overlap the first anode electrodes AE1 and the second anode electrodes AE2. The transparent patterns TPP may be spaced (e.g., spaced apart) from each other and may be disposed within the openings OP of the pixel defining layer PDL.

In one or more embodiments, the transparent patterns TPP may include first to third transparent patterns TPP1 to TPP3 that overlap the first to third sub-pixel areas SPA1 to SPA3, respectively. In the first to third transparent patterns TPP1 to TPP3, a thickness in at least one of the first to third sub-pixel areas SPA1 to SPA3 may be different from thicknesses in the remaining areas. For example, the first to third transparent patterns TPP1 to TPP3 may have different thicknesses.

For example, the thickness t1 of the first transparent pattern TPP1 may be greater than the thickness t3 of the third transparent pattern TPP3, and the thickness t3 of the third transparent pattern TPP3 may be greater than the thickness t2 of the second transparent pattern TPP2. However, the present disclosure is not limited thereto, and the thicknesses of the first to third transparent patterns TPP1 to TPP3 may be varied for optimal light output efficiency.

The transparent patterns TPP may be composed of a material having high transmittance. For example, the transparent patterns TPP may be composed of the same material as a hole injection layer of the light emitting structure EMS. For another example, the transparent patterns TPP may be composed of the same material as resin portions CCP1a, CCP2a, and CCP3a included in a color filter layer CFL.

The light emitting structure EMS may be disposed entirely on the second anode electrodes AE2 and the pixel defining layer PDL. The light emitting structure EMS may be disposed on the anode electrodes AE exposed by the openings OP of the pixel defining layer PDL. The light emitting structure EMS may include a light emitting layer configured to generate light, an electron injection layer configured to inject electrons, an electron transport layer configured to transport electrons, a hole transport layer configured to transport holes, a hole injection layer configured to inject holes, and/or the like.

The light emitting structure EMS may fill the openings OP of the pixel defining layer PDL and may be disposed entirely over the pixel defining layer PDL. In other words, the light emitting structure EMS may extend across the first to third sub-pixel areas SPA1 to SPA3.

The cathode electrode CE may be disposed on the light emitting structure EMS. The cathode electrode CE may extend across the first to third sub-pixels SP1 to SP3. In this way, the cathode electrode CE may be provided as a common electrode for the first to third sub-pixels SP1 to SP3.

The cathode electrode CE may be a thin metal layer having a thickness sufficient to transmit light emitted from the light emitting structure EMS. The cathode electrode CE may be formed of a metal material to have a relatively thin thickness or may be formed of a transparent conductive material. In one or more embodiments, the cathode electrode CE may include at least one of various transparent conductive materials, including indium tin oxide, indium zinc oxide, indium tin zinc oxide, aluminum zinc oxide, gallium zinc oxide, zinc tin oxide, and gallium tin oxide. In another embodiment, the cathode electrode CE may include silver (Ag), magnesium (Mg), and/or mixtures thereof. However, the material of the cathode electrode CE is not limited thereto.

It can be understood that one of the second anode electrodes AE2, a portion of the light emitting structure EMS overlapping therewith, and a portion of the cathode electrode CE overlapping therewith constitute one light emitting element LD (see FIG. 2). That is, each of light emitting elements LD1, LD2, and LD3 of the first to third sub-pixels SP1 to SP3 may include one second anode electrode AE2, a portion of the light emitting structure EMS overlapping therewith, and a portion of the cathode electrode CE overlapping therewith. In each of the first to third sub-pixels SP1 to SP3, holes injected from the second anode electrode AE2 and electrons injected from the cathode electrode CE may be transported into the light emitting layer of the light emitting structure EMS to form excitons, and light may be generated when the excitons transition from an excited state to a ground state. The luminance of the light may be determined by the amount of current flowing through the light emitting layer. The wavelength range of the light generated may be determined by the composition of the light emitting layer.

An encapsulation layer TFE may be disposed on the cathode electrode CE. The encapsulation layer TFE may cover light emitting elements LD1, LD2, and LD3 and/or the pixel circuit layer PCL. The encapsulation layer TFE may be configured to prevent oxygen and/or moisture from penetrating into the light emitting elements LD1, LD2, and LD3. In one or more embodiments, the encapsulating layer TFE may include a structure in which one or more inorganic films and one or more organic films are alternately laminated. For example, the inorganic film may include silicon nitride, silicon oxide, silicon oxynitride (SiOxNy), and/or the like. For example, the organic film may include an organic insulating material such as an acrylic resin, an epoxy resin, a phenol resin, a polyamide resin, a polyimide resin, an unsaturated polyester resin, a polyphenylenether resin, a polyphenylenesulfide resin, and/or benzocyclobutene (BCB). However, the materials of the organic and inorganic films that constitute the encapsulating layer TFE are not limited thereto.

In order to improve the encapsulation efficiency of the encapsulation layer TFE, the encapsulation layer TFE may further include a thin film including aluminum oxide (AlOx). The thin film including aluminum oxide may be positioned on an upper surface of the encapsulation layer TFE facing the light functional layer LFL and/or on a lower surface of the encapsulation layer TFE facing the light emitting elements LD1, LD2, and LD3.

The thin film including aluminum oxide may be formed by an atomic layer deposition (ALD) method. However, the present disclosure is not limited thereto. The encapsulation layer TFE may further include a thin film formed of at least one of various materials suitable for improving encapsulation efficiency.

A spacer CS may be disposed on the encapsulation layer TFE. The spacer CS may maintain a gap between the display element layer DPL and the light functional layer LFL. A filling layer FL may fill the gap formed by the spacer CS on the encapsulation layer TFE.

The light functional layer LFL may be disposed on the filling layer FL. The light functional layer LFL may include a first capping layer CPL1, a color conversion layer CCL, a second capping layer CPL2, a low refractive index layer LRL, and a color filter layer CFL.

The first capping layer CPL1 may be disposed on the filling layer FL. The first capping layer CPL1 may be configured to prevent oxygen and/or moisture from penetrating into the color conversion layer CCL.

The color conversion layer CCL may be disposed on the first capping layer CPL1. The color conversion layer CCL may include color conversion patterns CCP and a bank layer BNK.

The bank layer BNK may include openings corresponding to the first to third sub-pixel areas SPA1 to SPA3. The bank layer BNK may include an organic material. The bank layer BNK may further include a light blocking material. For example, at least a portion of the bank layer BNK may include a light blocking material such as a black pigment, a dye, carbon black, and/or the like.

The color conversion patterns CCP may be disposed within the openings of the bank layer BNK. That is, the bank layer BNK may surround the color conversion patterns CCP, and the color conversion patterns CCP may overlap the first to third sub-pixel areas SPA1 to SPA3. The color conversion patterns CCP may include first to third color conversion patterns CCP1 to CCP3, and the first to third color conversion patterns CCP1 to CCP3 may be spaced (e.g., spaced apart) from each other.

The first color conversion pattern CCP1 may overlap the first sub-pixel area SPA1. The first color conversion pattern CCP1 may convert light incident on the first color conversion pattern CCP1 into red light. For example, the first color conversion pattern CCP1 may include a resin portion CCP1a, scatterers CCP1b, and wavelength conversion particles CCP1c.

The wavelength conversion particles CCP1c may include a quantum dot. The quantum dot may absorb the incident light and emit light having a different wavelength from the incident light. For example, the wavelength conversion particles CCP1c of the first color conversion pattern CCP1 may include a quantum dot that absorbs the incident light and emits red light. Accordingly, the first color conversion pattern CCP1 may convert the incident light and emit red light.

The second color conversion pattern CCP2 may overlap the second sub-pixel area SPA2 and a second emission area. The second color conversion pattern CCP2 may convert light incident on the second color conversion pattern CCP2 into green light. For example, the second color conversion pattern CCP2 may include a resin portion CCP2a, scatterers CCP2b, and wavelength conversion particles CCP2c.

The wavelength conversion particles CCP2c may include a quantum dot. The quantum dot may absorb the incident light and emit light having a different wavelength from the incident light. For example, the wavelength conversion particles CCP2c of the second color conversion pattern CCP2 may include a quantum dot that absorbs the incident light and emits green light. Accordingly, the second color conversion pattern CCP2 may convert the incident light and emit green light.

The third color conversion pattern CCP3 may overlap the third sub-pixel area SPA3 and a third emission area. The third color conversion pattern CCP3 may transmit light incident on the third color conversion pattern CCP3. For example, the third color conversion pattern CCP3 may include a resin portion CCP3a and scatterers CCP3b.

However, the present disclosure is not limited thereto, and the third color conversion pattern CCP3 may convert light incident on the third color conversion pattern CCP3 into blue light. For example, the third color conversion pattern CCP3 may include a resin portion CCP3a, scatterers CCP3b, and wavelength conversion particles. For example, the wavelength conversion particles of the third color conversion pattern CCP3 may include a quantum dot that absorbs the incident light and emits blue light. Accordingly, the third color conversion pattern CCP3 may convert the incident light and emit blue light.

The second capping layer CPL2 may be disposed on the color conversion layer CCL. The second capping layer CPL2 may entirely cover an upper surface of the color conversion layer CCL. The second capping layer CPL2 may include an inorganic material.

The low refractive index layer LRL may be disposed on the second capping layer CPL2. The low refractive index layer LRL may increase the luminance of the display panel DP by improving light extraction efficiency. The low refractive index layer LRL may include an organic material.

The color filter layer CFL may be disposed between the low refractive index layer LRL and the second substrate SUB2. The color filter layer CFL may be configured to filter light emitted from the light emitting structure EMS to selectively output light of a wavelength range or color corresponding to each sub-pixel.

The color filter layer CFL may include first to third color filter patterns CF1, CF2, and CF3.

The first color filter pattern CF1 may overlap the first sub-pixel area SPA1 and may selectively transmit red light. In this case, the incident light that is not converted by the first color conversion pattern CCP1 may be blocked by the first color filter pattern CF1. Accordingly, in the first sub-pixel area SPA1, red light may be emitted to the outside (that is, in the third direction DR3).

The second color filter pattern CF2 may overlap the second sub-pixel area SPA2 and may selectively transmit green light. In this case, the incident light that is not converted by the second color conversion pattern CCP2 may be blocked by the second color filter pattern CF2. Accordingly, in the second sub-pixel area SPA2, green light may be emitted to the outside.

The third color filter pattern CF3 may overlap the third sub-pixel area SPA3 and may selectively transmit blue light. In this case, the incident light that is not converted by the third color conversion pattern CCP3 may be blocked by the third color filter pattern CF3. Accordingly, in the third sub-pixel area SPA3, blue light may be emitted to the outside.

In one or more embodiments, the first anode electrodes AE1 may function as full mirrors, and the cathode electrode CE may function as a half mirror. For example, each of the first anode electrodes AE1 and the cathode electrode CE may provide a resonant structure in the corresponding sub-pixel. Light emitted from the light emitting layer of the light emitting structure EMS may be amplified by going back and forth between a corresponding reflective electrode (e.g., the first anode electrodes AE1) and the cathode electrode CE, and the amplified light may be output through the cathode electrode CE. In this way, the distance d1, d2, or d3 between each first anode electrode AE1 and the cathode electrode CE may be understood as a resonance distance for light emitted from the light emitting layer of the corresponding light emitting structure EMS.

In one or more embodiments, the resonance distance may be adjusted to match the wavelength of light emitted from each of the first to third sub-pixel areas SPA1 to SPA3. The resonance distance may be related to the wavelength of light emitted from each of the first to third sub-pixel areas SPA1 to SPA3.

For example, in the first sub-pixel area SPA1 where red light is emitted, the distance d1 between the first anode electrode AE1 and the cathode electrode CE may be the largest. In the second sub-pixel area SPA2 where green light is emitted, the distance d2 between the first anode electrode AE1 and the cathode electrode CE may be the smallest. In the third sub-pixel area SPA3 where blue light is emitted, the distance d3 between the first anode electrode AE1 and the cathode electrode CE may be smaller than the distance d1 in the first sub-pixel area SPA1 and larger than the distance d2 in the second sub-pixel area SPA2.

A transparent pattern TPP may be disposed between each first anode electrode AE1 and each second anode electrode AE2 to adjust the resonance distance in each of the first to third sub-pixel areas SPA1 to SPA3. That is, the distance between each first anode electrode AE1 and the cathode electrode CE may be controlled by controlling the thickness of each transparent pattern TPP. Because the distance d1, d3, or d2 between the first anode electrode AE1 and the cathode electrode CE decrease in the order of the first sub-pixel area SPA1, the third sub-pixel area SPA3, and the second sub-pixel area SPA2, the thickness of the transparent pattern TPP may also decrease in the order of the first sub-pixel area SPA1, the third sub-pixel area SPA3, and the second sub-pixel area SPA2.

That is, by controlling the thickness of the transparent pattern TPP between the first anode electrode AE1 and the second anode electrode AE2 that overlap each other, the distance between the first anode electrode AE1 and the second anode electrode AE2 may be controlled. As a result, the distance between each first anode electrode AE1 and the cathode electrode CE may be controlled by controlling the thickness of the transparent pattern TPP. By controlling the distance between each first anode electrode AE1 and cathode electrode CE, each of the first to third sub-pixel areas SPA1 to SPA3 may have an optimal resonance distance. Accordingly, the light output efficiency can be improved, and a white angle difference (WAD) phenomenon, in which the color of a white image changes depending on the viewing angle, can be improved.

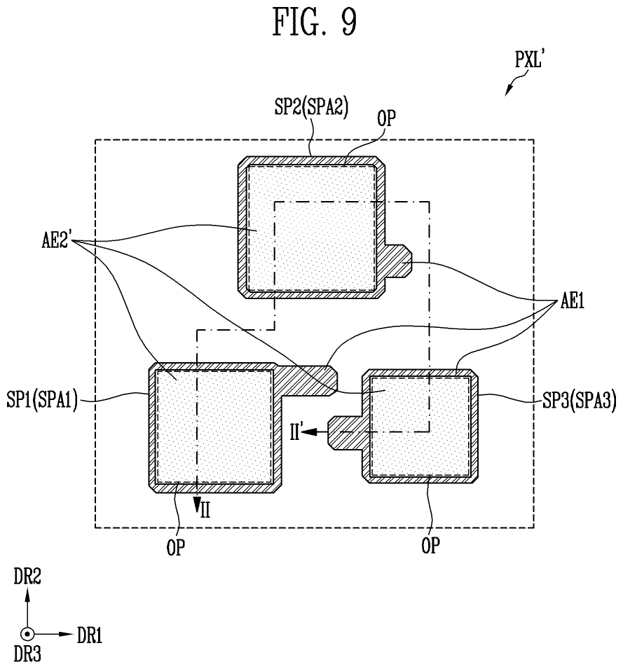

FIG. 9 is a plan view illustrating an embodiment of another one of the pixels of FIG. 4. The embodiment according to FIG. 9 may differ from the embodiment according to FIG. 7 in that the transparent pattern TPP has conductivity and the contact hole CNT connecting the first anode electrode AE1 and the second anode electrode AE2′ is not formed.

Referring to FIG. 9, a pixel PXL′ may include first to third sub-pixels SP1 to SP3.

Each of the first to third sub-pixels SP1 to SP3 may include a first anode electrode AE1 and a second anode electrode AE2′. First anode electrodes AE1 may be disposed in first to third sub-pixel areas SPA1 to SPA3, respectively, and second anode electrodes AE2′ may also be disposed in the first to third sub-pixel areas SPA1 to SPA3, respectively.

The first anode electrodes AE1 may be spaced (e.g., spaced apart) from each other. The second anode electrodes AE2′ may be disposed on the first anode electrodes AE1, respectively, and may entirely overlap the first anode electrodes AE1. In addition, the second anode electrodes AE2′ may be electrically connected to the first anode electrodes AE1, respectively. Like the first anode electrodes AE1, the second anode electrodes AE2′ may be spaced (e.g., spaced apart) from each other.

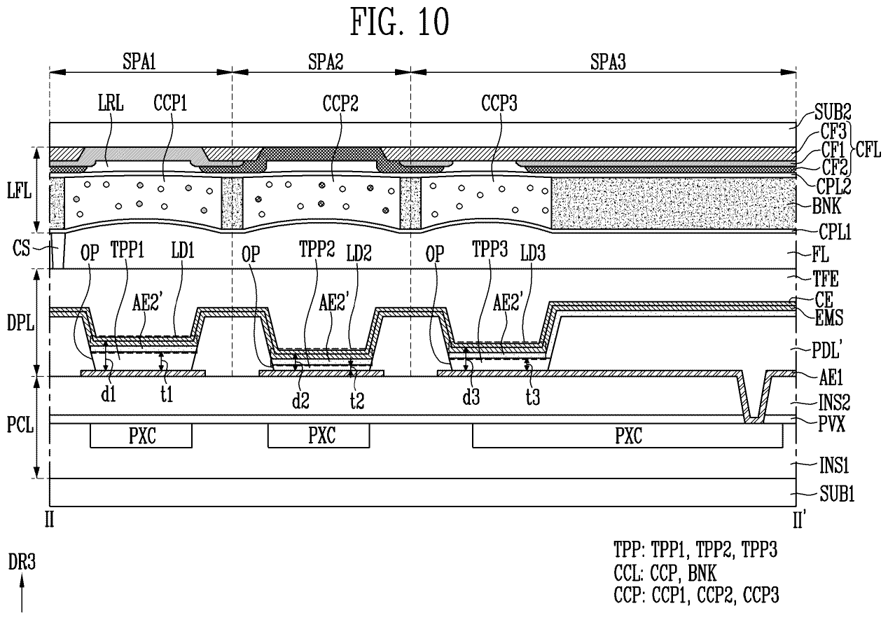

The second anode electrodes AE2′ may be electrically connected to the first anode electrodes AE1 through the transparent patterns TPP (see FIG. 10). Accordingly, contact holes for connecting the first anode electrodes AE1 and the second anode electrodes AE2′ to each other may not be defined in the first to third sub-pixel areas SPA1 to SPA3.

At least one opening OP may be defined in each of the first to third sub-pixel areas SPA1 to SPA3. Openings OP may overlap the first anode electrodes AE1, respectively. Since the second anode electrodes AE2′ overlap the first anode electrodes AE1, respectively, the openings OP may also overlap the second anode electrodes AE2′, respectively.

A pixel defining layer PDL′ (see FIG. 10) may be disposed between the first anode electrodes AE1 and the second anode electrodes AE2′. The pixel defining layer PDL′ may define only openings OP. Accordingly, each of the first anode electrodes AE1 may overlap at least one opening OP under the pixel defining layer PDL′. In addition, each of the second anode electrodes AE2′ may overlap at least one opening OP on the pixel defining layer PDL′.

FIG. 10 is a cross-sectional view taken along the line II-II′ in FIG. 9.

Referring to FIG. 10, the pixel defining layer PDL′ may be disposed between the first anode electrodes AE1 and the second anode electrodes AE2′. The pixel defining film PDL′ may define the openings OP that partially overlap the first anode electrodes AE1. That is, the openings OP may partially expose upper surfaces of the first anode electrodes AE1. As the pixel defining layer PDL′ defines the openings OP that partially overlap the first anode electrodes AE1, the pixel defining layer PDL′ may cover edges of the first anode electrodes AE1. The pixel defining layer PDL′ may define only the openings OP that overlap the first anode electrodes AE1.

The transparent patterns TPP may be disposed between the first anode electrodes AE1 and the second anode electrodes AE2′. That is, the transparent patterns TPP may overlap the first anode electrodes AE1 and the second anode electrodes AE2′. The transparent patterns TPP may be spaced (e.g., spaced apart) from each other and disposed within the openings OP of the pixel defining layer PDL′, respectively.

The transparent patterns TPP may be composed of a material having high transmittance and conductivity. That is, through this, the transparent patterns TPP may directly contact the first anode electrodes AE1 and the second anode electrodes AE2′ that overlap each other and connect the first anode electrodes AE1 and the second anode electrodes AE2′ to each other. Therefore, in this case, separate contact holes CNT for connecting the first anode electrodes AE1 and the second anode electrodes AE2′ may not be required.

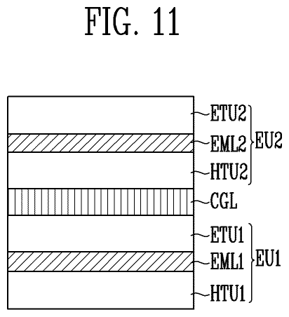

FIG. 11 is a cross-sectional view illustrating an embodiment of a portion of a light emitting structure included in one of first to third light emitting elements of FIG. 8 or FIG. 10.

Referring to FIG. 11, the light emitting structure may have a tandem structure in which first and second light emitting units EU1 and EU2 are laminated. The light emitting structure may be configured substantially the same in each of the first to third light emitting elements LD1 to LD3 of FIG. 8.

Each of the first and second light emitting units EU1 and EU2 may include at least one light emitting layer that generates light according to an applied current. The first light emitting unit EU1 may include a first light emitting layer EML1, a first electron transport unit ETU1, and a first hole transport unit HTU1. The first light emitting layer EML1 may be disposed between the first electron transport unit ETU1 and the first hole transport unit HTU1. The second light emitting unit EU2 may include a second light emitting layer EML2, a second electron transport unit ETU2, and a second hole transport unit HTU2. The second light emitting layer EML2 may be disposed between the second electron transport unit ETU2 and the second hole transport unit HTU2.

Each of the first and second hole transport units HTU1 and HTU2 may include a hole injection layer and/or a hole transport layer, and may further include a hole buffer layer, an electron blocking layer, and/or the like as needed. The first and second hole transport units HTU1 and HTU2 may have the same configuration or different configurations.

Each of the first and second electron transport units ETU1 and ETU2 may include an electron injection layer and/or an electron transport layer, and may further include an electron buffer layer, a hole blocking layer, and/or the like as needed. The first and second electron transport units ETU1 and ETU2 may have the same configuration or different configurations.

A connection layer, which may be provided in the form of a charge generation layer CGL, may be disposed between the first light emitting unit EU1 and the second light emitting unit EU2 to connect them to each other. In one or more embodiments, the charge generation layer CGL may have a stacked structure of a p dopant layer and an n dopant layer. For example, the p dopant layer may include a p-type dopant such as HAT-CN, TCNQ, NDP-9, and/or the like, and the n dopant layer may include an alkali metal, an alkaline earth metal, a lanthanide metal, or a combination thereof. However, the present disclosure is not limited thereto.

In one or more embodiments, the first light emitting layer EML1 and the second light emitting layer EML2 may generate light of different colors. The light emitted from each of the first light emitting layer EML1 and the second light emitting layer EML2 may be mixed and visually recognized as white light. For example, the first light emitting layer EML1 may generate blue light, and the second light emitting layer EML2 may generate yellow light. In one or more embodiments, the second light emitting layer EML2 may include a structure in which a first sub-light emitting layer configured to generate red light and a second sub-light emitting layer configured to generate green light are laminated. The red light and the green light may be mixed to provide yellow light. In this case, an intermediate layer configured to perform the function of transporting holes and/or the function of blocking the transport of electrons may be further disposed between the first and second sub-emitting layers.

In another embodiment, the first light emitting layer EML1 and the second light emitting layer EML2 may generate light of the same color.

The light emitting structure may be formed by a vacuum deposition method, an inkjet printing method, and/or the like, but the present disclosure is not limited thereto.

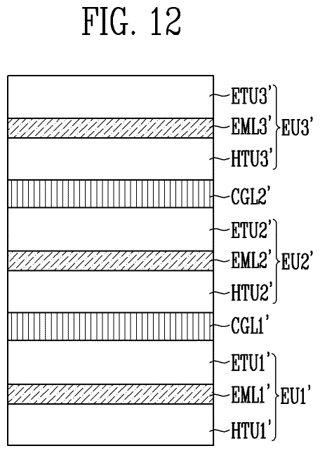

FIG. 12 is a cross-sectional view illustrating another embodiment of a portion of the light emitting structure included in one of the first to third light emitting elements of FIG. 8 or FIG. 10.

Referring to FIG. 12, the light emitting structure may have a tandem structure in which first to third light emitting units EU1′ to EU3′ are laminated. The light emitting structure may be configured substantially the same in each of the first to third light emitting elements LD1 to LD3 of FIG. 8.

Each of the first to third light emitting units EU1′ to EU3′ may include a light emitting layer that generates light according to an applied current. The first light emitting unit EU1′ may include a first light emitting layer EML1′, a first electron transport unit ETU1′, and a first hole transport unit HTU1′. The first light emitting layer EML1′ may be disposed between the first electron transport unit ETU1′ and the first hole transport unit HTU1′. The second light emitting unit EU2′ may include a second light emitting layer EML2′, a second electron transport unit ETU2′, and a second hole transport unit HTU2′. The second light emitting layer EML2′ may be disposed between the second electron transport unit ETU2′ and the second hole transport unit HTU2′. The third light emitting unit EU3′ may include a third light emitting layer EML3′, a third electron transport unit ETU3′, and a third hole transport unit HTU3′. The third light emitting layer EML3′ may be disposed between the third electron transport unit ETU3′ and the third hole transport unit HTU3′.

Each of the first to third hole transport units HTU1′ to HTU3′ may include a hole injection layer and/or a hole transport layer, and may further include a hole buffer layer, an electron blocking layer, and/or the like as needed. The first to third hole transport units HTU1′ to HTU3′ may have the same configuration or different configurations.

Each of the first to third electron transport units ETU1′ to ETU3′ may include an electron injection layer and/or an electron transport layer, and may further include an electron buffer layer, a hole blocking layer, and/or the like as needed. The first to third electron transport units ETU1′ to ETU3′ may have the same configuration or different configurations.

A first charge generation layer CGL1′ may be disposed between the first light emitting unit EU1′ and the second light emitting unit EU2′. A second charge generation layer CGL2′ may be disposed between the second light emitting unit EU2′ and the third light emitting unit EU3′.

In one or more embodiments, the first to third light emitting layers EML1′ to EML3′ may generate light of different colors. The light emitted from each of the first to third light emitting layers EML1′ to EML3′ may be mixed and visually recognized as white light. For example, the first light emitting layer EML1′ may generate blue light, the second light emitting layer EML2′ may generate green light, and the third light emitting layer EML3′ may generate red light.

In another embodiment, two or more of the first to third light emitting layers EML1′ to EML3′ may generate light of the same color.

Unlike those shown in FIGS. 11 and 12, the light emitting structure of FIG. 8 or FIG. 10 may include one light emitting unit in each of the first to third light emitting elements LD1 to LD3. In this case, the light emitting units included in the first to third light emitting elements LD1 to LD3 may be configured to emit light of different colors. For example, the light emitting unit of the first light emitting element LD1 may emit red light, the light emitting unit of the second light emitting element LD2′ may emit green light, and the light emitting unit of the third light emitting element LD3 may emit blue light. In this case, the light emitting units of the first to third sub-pixels SP1 to SP3 may be separated from each other, and each of them may be disposed within the opening OP (see FIG. 8) of the pixel defining layer PDL or PDL′ (see FIG. 8 or FIG. 10). In this case, at least some of the color filters CF1 to CF3 may be omitted.

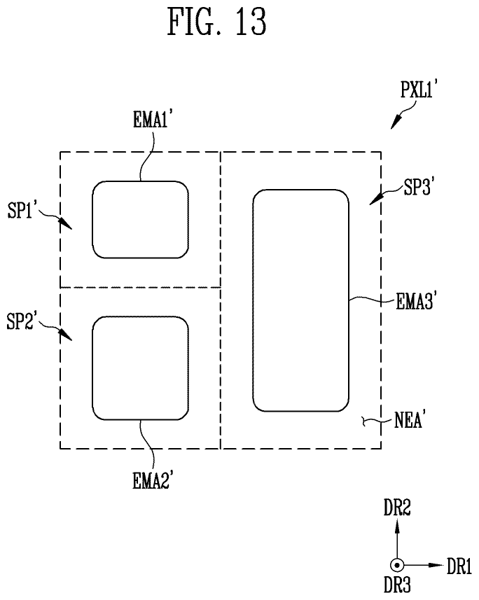

FIG. 13 is a plan view illustrating another embodiment of one of the pixels of FIG. 4.

Referring to FIG. 13, a first pixel PXL1′ may include first to third sub-pixels SP1′ to SP3′.

The first sub-pixel SP1′ may include a first emission area EMA1′ and a non-emission area NEA′ around the first emission area EMA1′. The second sub-pixel SP2′ may include a second emission area EMA2′ and the non-emission area NEA′ around the second emission area EMA2′. The third sub-pixel SP3′ may include a third emission area EMA3′ and the non-emission area NEA′ around the third emission area EMA3′.

The first sub-pixel SP1′ and the second sub-pixel SP2′ may be arranged along the second direction DR2. The third sub-pixel SP3′ may be arranged in the first direction DR1 with respect to each of the first and second sub-pixels SP1′ and SP2′.

The second sub-pixel SP2′ may have a larger area than the first sub-pixel SP1′, and the third sub-pixel SP3′ may have a larger area than the second sub-pixel SP2′. Accordingly, the second emission area EMA2′ may have a larger area than the first emission area EMA1′, and the third emission area EMA3′ may have a larger area than the second emission area EMA2′. However, the present disclosure is not limited thereto. For example, the first and second sub-pixels SP1′ and SP2′ may have substantially the same area, and the third sub-pixel SP3′ may have a larger area than the first and second sub-pixels SP1′ and SP2′. In this way, the areas of the first to third sub-pixels SP1′ to SP3′ may be varied in various ways depending on embodiments.

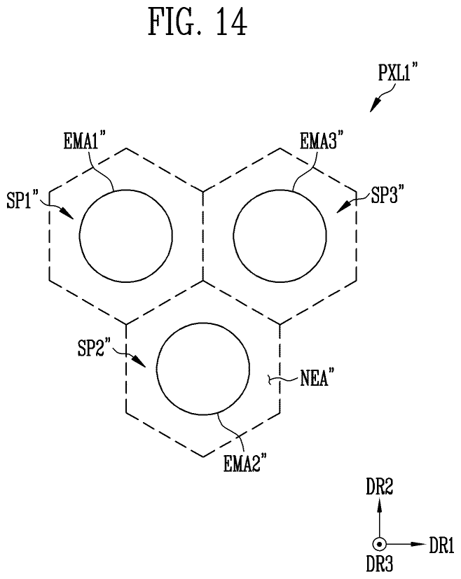

FIG. 14 is a plan view illustrating still another embodiment of one of the pixels of FIG. 4.

Referring to FIG. 14, a first sub-pixel SP1″ may include a first emission area EMA1″ and a non-emission area NEA″ around the first emission area EMA1″. A second sub-pixel SP2″ may include a second emission area EMA2″ and the non-emission area NEA″ around the second emission area EMA2″. A third sub-pixel SP3″ may include a third emission area EMA3″ and the non-emission area NEA″ around the third emission area EMA3″.

The first to third sub-pixels SP1″ to SP3″ may have a polygonal shape when viewed in the third direction DR3. For example, the shape of the first to third sub-pixels SP1″ to SP3″ may be hexagonal, as shown in FIG. 13.

The first to third emission areas EMA1″ to EMA3″ may have a circular shape when viewed in the third direction DR3. However, the present disclosure is not limited thereto. For example, the first to third emission areas EMA1″ to EMA3″ may have a polygonal shape.

The first and third sub-pixels SP1″ and SP3″ may be arranged along the first direction DR1. The second sub-pixel SP2″ may be arranged in a direction inclined at an acute angle (or diagonal direction) with respect to the first sub-pixel SP1″ based on the second direction DR2.

The arrangements of the sub-pixels shown in FIGS. 7, 13, and 14 are only examples, and embodiments are not limited thereto. Each pixel may include two or more sub-pixels, the sub-pixels may be arranged in various ways, each of the sub-pixels may have various shapes, and each of the emission areas of the sub-pixels may also have various shapes.

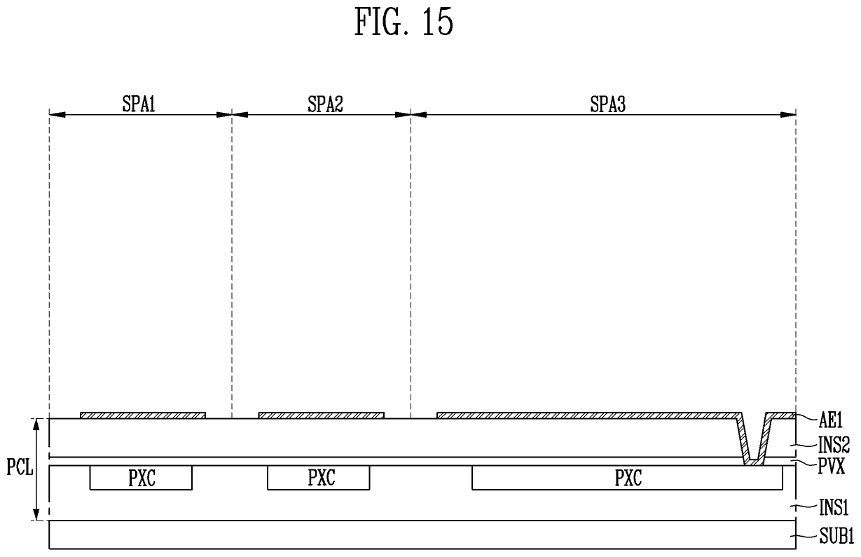

FIGS. 15-21 are diagrams illustrating a method of manufacturing a display device according to one or more embodiments of the present disclosure. FIGS. 15-21 show a method of manufacturing the display device according to the embodiments described above with reference to FIGS. 1-8. Content that may overlap with the above will be briefly described or not repeated.

Referring to FIG. 15, a first insulating layer INS1 and circuit elements PXC may be formed on a first substrate SUB1. A passivation layer PVX may be formed on the first insulating layer INS1 and the circuit elements PXC. A second insulating layer INS2 may be formed on the passivation layer PVX. Accordingly, a pixel circuit layer PCL including the first insulating layer INS1, the circuit elements PXC, the passivation layer PVX, and the second insulating layer INS2 may be formed.

First anode electrodes AE1 may be formed on the second insulating layer INS2. The first anode electrodes AE1 may be formed in the first to third sub-pixel areas SPA1 to SPA3, respectively, and may be spaced (e.g., spaced apart) from each other.

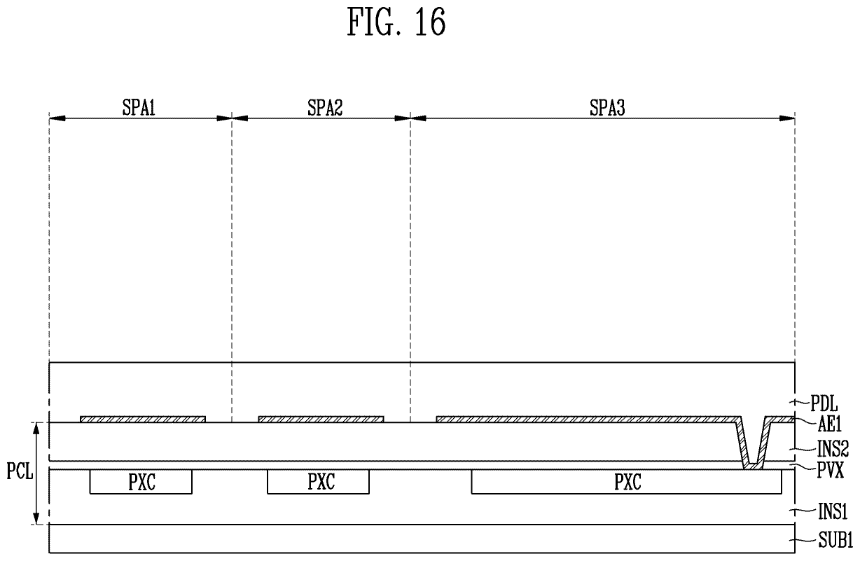

Referring to FIG. 16, a pixel defining layer PDL may be formed on the second insulating layer INS2. The pixel defining layer PDL may cover the first anode electrodes AE1 and may be formed entirely on the first anode electrodes AE1.

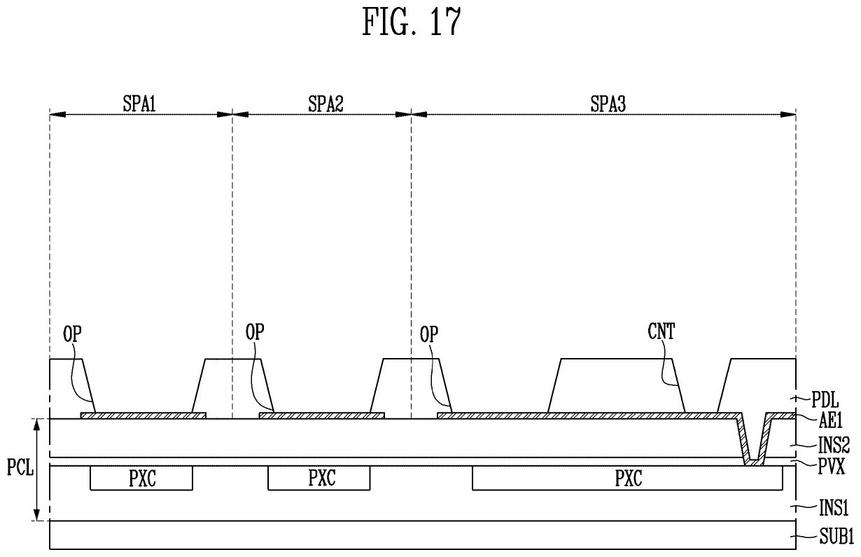

Referring to FIG. 17, in one or more embodiments, openings OP and contact holes CNT may be formed in the pixel defining layer PDL. The openings OP may be formed to overlap the first anode electrodes AE1, respectively. The contact holes CNT may be formed to overlap the first anode electrodes AE1, respectively, and to be spaced (e.g., spaced apart) from the openings OP. Accordingly, upper surfaces of the first anode electrodes AE1 may be partially exposed through the openings OP and the contact holes CNT.

In another embodiment, only the openings OP may be formed in the pixel defining layer PDL (see FIGS. 9 and 10).

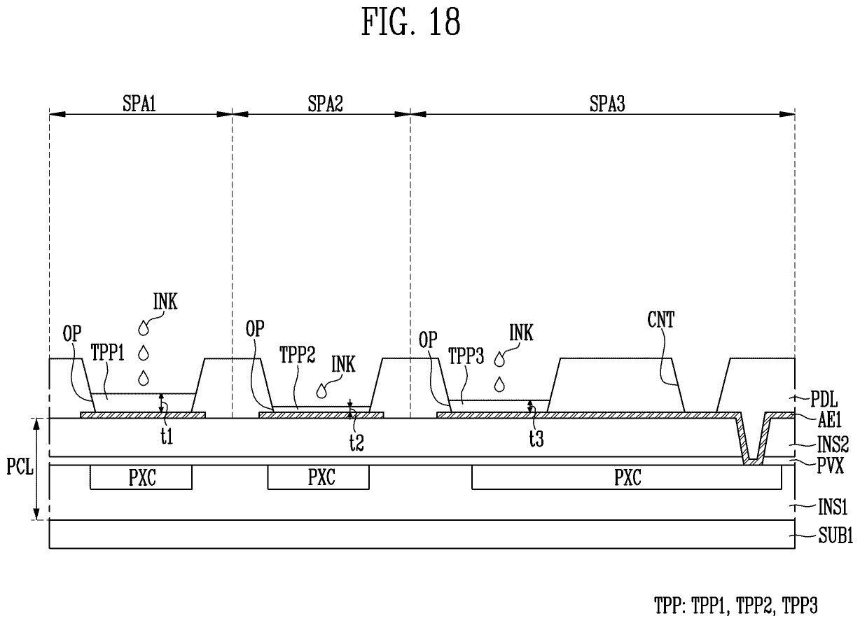

Referring to FIG. 18, transparent patterns TPP may be formed on the first anode electrodes AE1, respectively. The transparent patterns TPP may include first to third transparent patterns TPP1 to TPP3. The first to third transparent patterns TPP1 to TPP3 may overlap the first to third sub-pixel areas SPA1 to SPA3, respectively, and may be formed within the openings OP, respectively.

The first to third transparent patterns TPP1 to TPP3 may be formed by an inkjet process. Accordingly, the first to third transparent patterns TPP1 to TPP3 may be individually formed within the openings OP. By controlling the amount of ink INK forming the first to third transparent patterns TPP1 to TPP3, the transparent patterns TPP may be formed such that the thickness in at least one of the first to third sub-pixel areas SPA1 to SPA3 is different from the thicknesses in the remaining areas. For example, by controlling the amount of ink INK forming the first to third transparent patterns TPP1 to TPP3 differently, the transparent patterns TPP overlapping the first to third sub-pixel areas SPA1 to SPA3 may be formed to have different thicknesses.

The first to third transparent patterns TPP1 to TPP3 may be formed with suitable thicknesses (e.g., predetermined thicknesses) t1, t2, and t3 within the openings OP by an inkjet process. For example, the thickness t1 of the first transparent pattern TPP1 may be greater than the thickness t3 of the third transparent pattern TPP3, and the thickness t3 of the third transparent pattern TPP3 may be greater than the thickness t2 of the second transparent pattern TPP2. However, the present disclosure is not limited thereto, and the first to third transparent patterns TPP1 to TPP3 may also have differential thicknesses through processes other than the inkjet process.

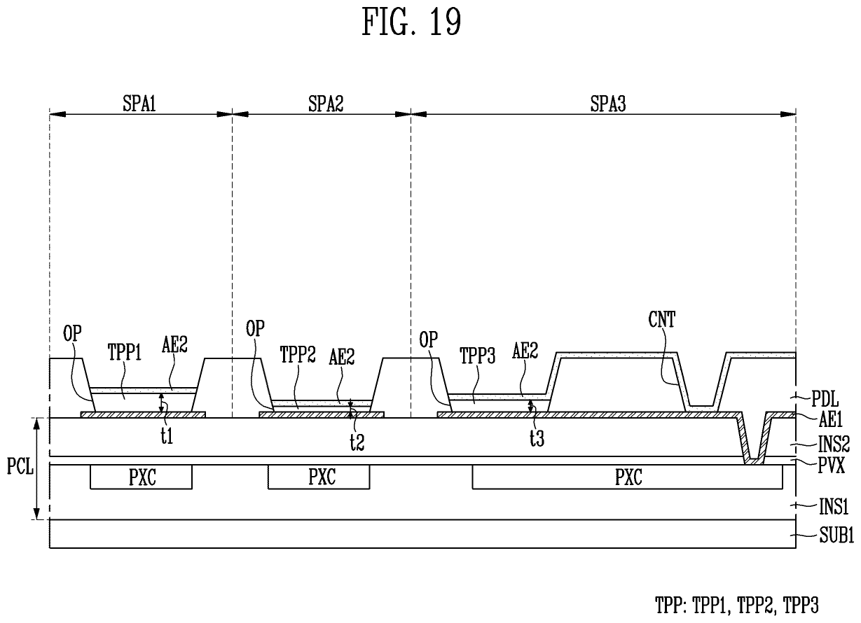

Referring to FIG. 19, second anode electrodes AE2 may be formed on the transparent patterns TPP and the pixel defining layer PDL. The second anode electrodes AE2 may be disposed on the first anode electrodes AE1, respectively, and formed to overlap the first anode electrodes AE1, respectively. In one or more embodiments, the second anode electrodes AE2 may be electrically connected to the first anode electrodes AE1 through the contact holes CNT, respectively. In another embodiment, when the transparent patterns TPP are formed of a conductive material, the second anode electrodes AE2 may be electrically connected to the first anode electrodes AE1 through the transparent patterns TPP, respectively (see FIG. 10).

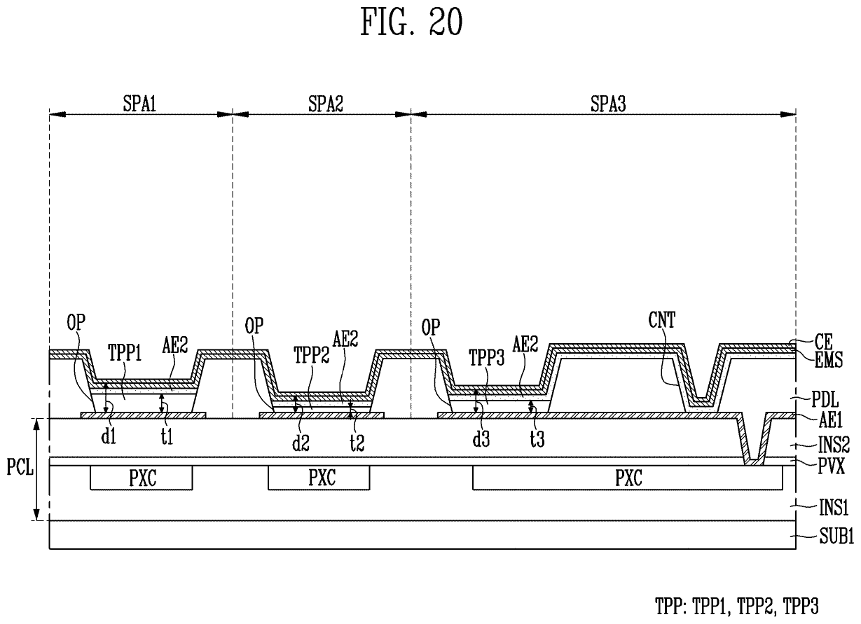

Referring to FIG. 20, a light emitting structure EMS may be formed entirely on the second anode electrodes AE2 and the pixel defining layer PDL. In addition, a cathode electrode CE may be formed entirely on the light emitting structure EMS.

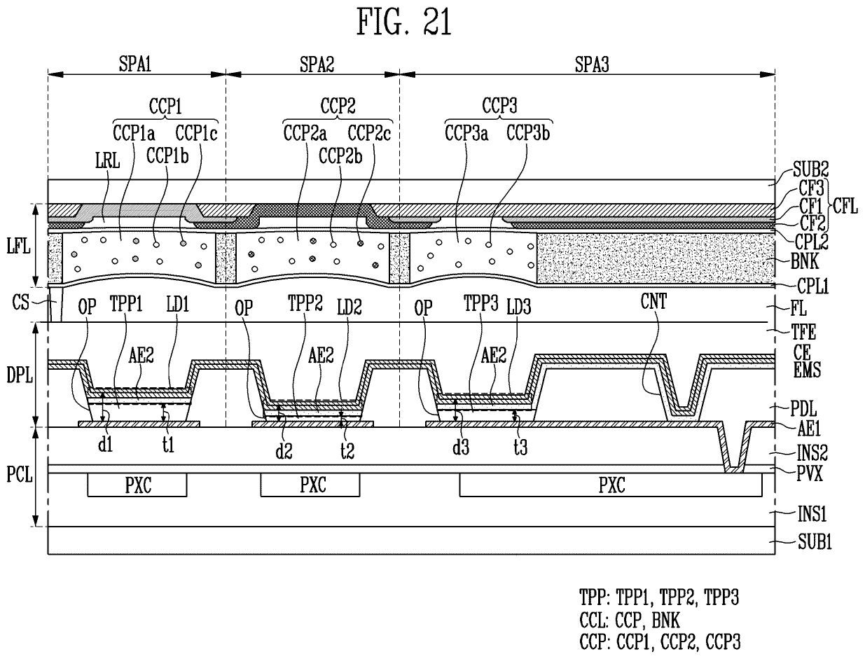

Referring to FIG. 21, an encapsulation layer TFE may be formed on the cathode electrode CE. A spacer CS and a filling layer FL may be formed on the encapsulation layer TFE. A first capping layer CPL1, a color conversion layer CCL, a second capping layer CPL2, a color filter layer CFL, and a second substrate SUB2 may be sequentially formed on the filling layer FL.

In one or more embodiments, because the transparent patterns TPP are formed by an inkjet process, the thickness of each of the transparent patterns TPP overlapping the first to third sub-pixel areas SPA1 to SPA3 can be controlled. By controlling the thickness of each of the transparent patterns TPP, each light emitting element may have an optimal resonance distance. Accordingly, the light output efficiency can be improved, and a white angle difference (WAD) phenomenon, in which the color of a white image changes depending on the viewing angle, can be improved.

In addition, when the transparent patterns TPP are conductive, because the first anode electrodes AE1 and the second anode electrodes AE2 may be connected to each other through the transparent patterns TPP, separate contact holes CNT are not required, so existing equipment can be used as is.

A display device according to one or more embodiments is applicable to various types of electronic devices. In one or more embodiments, an electronic device includes the above-described display device and may further include other modules or devices having additional functions in addition to the display device.

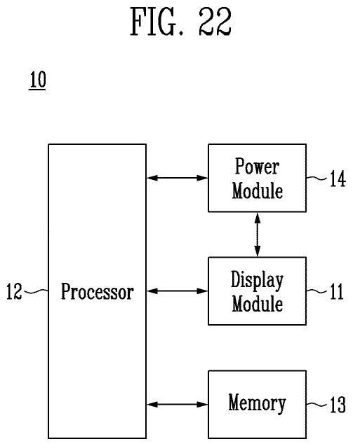

FIG. 22 is a block diagram of an electronic device according to one or more embodiments. Referring to FIG. 22, the electronic device 10 may include a display module 11, a processor 12, a memory 13, and a power module 14.

The processor 12 may include a central processing unit (CPU), an application processor (AP), a graphic processing unit (GPU), a communication processor (CP), an image signal processor (ISP), and/or a controller.

The memory 13 may store data and/or information used to operate the processor 12 or the display module 11. When the processor 12 executes an application stored in the memory 13, image data signals and/or input control signals may be transferred to the display module 11. The display module 11 may process the provided signals and output image information on a display screen.

The power module 14 may include a power supply module, such as a power adapter or a battery device, and a power conversion module. The power conversion module converts power supplied by the power supply module and generates power to operate the electronic device 10.

At least one of the above-described components of the electronic device 10 may be included in the display device according to one or more embodiments as described above. In addition, in terms of functionality, some of the individual modules included in one module may be included in the display device and others may be provided separately from the display device. For example, the display module 11 is included in the display device, whereas the processor 12, the memory 13, and/or the power module 14 are not included in the display device and are instead provided separately in the electronic device 10.

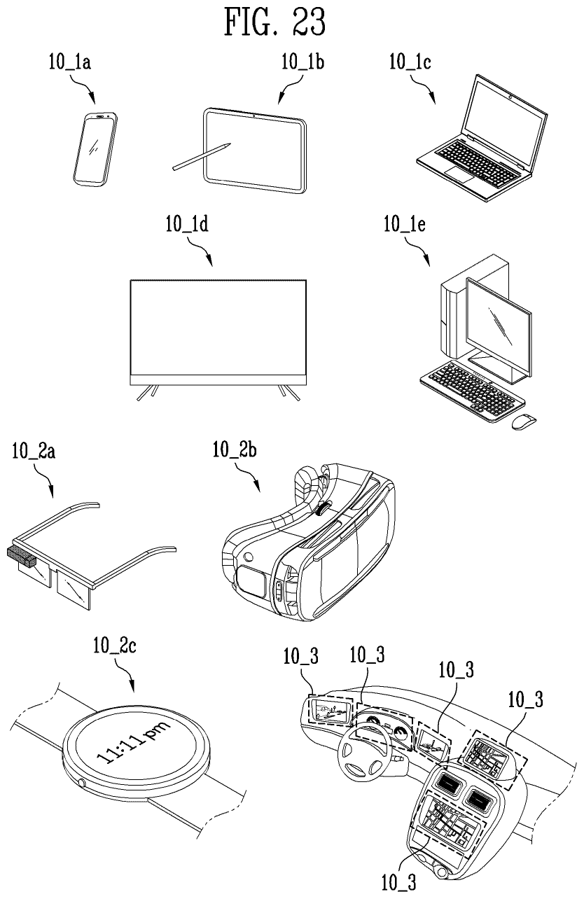

FIG. 23 shows schematic views of various embodiments of an electronic device.

Referring to FIG. 23, various types of electronic devices to which embodiments of a display device are applied may include an electronic device to display images such as a smartphone 10_1a, a tablet PC 10_1b, a laptop computer 10_1c, a television (TV) 10_1d, and a desktop monitor 10_1e, a wearable electronic device including a display module such as smart glasses 10_2a, a head-mounted display (HMD) 10_2b, and a smart watch 10_2c, and an automotive electronic device 10_3 including a display module such as a center information display (CID) disposed at the instrument cluster, the center fascia, and the dashboard of a vehicle, and a room mirror display.

According to the embodiments described above, the transparent patterns may be disposed between the first anode electrodes and the second anode electrodes, and may have a thickness in at least one of the sub-pixel areas that is different from thicknesses in the remaining areas. Therefore, the distance between each of the first anode electrodes and the cathode electrode may be set differently for each sub-pixel area. Accordingly, the resonance distance for light emitted from the light emitting layer of the light emitting structure may be controlled so that each light emitting element may have an optimal resonance distance. Accordingly, the light output efficiency can be improved, and the white angle difference (WAD) phenomenon, in which the color of a white image changes depending on the viewing angle, can be improved.

Effects, aspects, and features according to the embodiments are not limited by the above-described contents, and more various other effects, aspects, and features are included in the present specification.

Although the technical spirit of the present disclosure has been specifically described according to the above-described embodiments, it should be noted that the above-described embodiments are intend to illustrate the present disclosure and not to limit the scope of the present disclosure. Those of ordinary skill in the art to which the present disclosure pertains will understand that various modifications are possible within the scope of the technical spirit of the present disclosure.

Therefore, the technical protection scope of the present disclosure is not limited to the detailed description described in the specification, but should be determined by the append claims and their equivalents. In addition, all changes or modifications derived from the meaning and scope of the claims and their equivalents should be construed as being included in the scope of the present disclosure.

What is claimed is:

1. A display device comprising:
a substrate;
first anode electrodes in first to third sub-pixel areas on the substrate and spaced from each other;
second anode electrodes on the first anode electrodes, overlapping the first anode electrodes, and electrically connected to the first anode electrodes;
a light emitting structure on the second anode electrodes;
a cathode electrode on the light emitting structure; and
transparent patterns between the first anode electrodes and the second anode electrodes, wherein a thickness of the transparent patterns in at least one of the first to third sub-pixel areas is different from thicknesses of the transparent patterns in other ones of the first to third sub-pixel areas.

2. The display device of claim 1, wherein the transparent patterns are spaced from each other.

3. The display device of claim 2, wherein the transparent patterns overlapping the first to third sub-pixel areas have different thicknesses.

4. The display device of claim 1, wherein each of the first anode electrodes is in direct contact with a corresponding one of the second anode electrodes.

5. The display device of claim 1, further comprising:
a pixel defining layer on the first anode electrodes and having openings overlapping the first anode electrodes.

6. The display device of claim 5, wherein the transparent patterns are within the openings, respectively.

7. The display device of claim 6, wherein the second anode electrodes overlap the openings, respectively.

8. The display device of claim 5, wherein the pixel defining layer have contact holes through which the first anode electrodes and the second anode electrodes are connected to each other, respectively.

9. The display device of claim 8, wherein in each of the first to third sub-pixel areas, at least one of the openings and at least one of the contact holes are located.

10. The display device of claim 9, wherein each of the first anode electrodes overlaps the at least one of the openings and the contact hole in the pixel defining layer.

11. The display device of claim 10, wherein each of the second anode electrodes overlaps the at least one of the openings and the contact hole in the pixel defining layer.

12. The display device of claim 1, wherein each of the first anode electrodes comprises at least one of silver or aluminum.

13. The display device of claim 1, wherein each of the second anode electrodes comprises a transparent conductive oxide.

14. The display device of claim 1, wherein the transparent patterns are conductive, and
wherein the first anode electrodes and the second anode electrodes are electrically connected to each other through the transparent patterns.

15. A method of manufacturing a display device comprising:
forming first anode electrodes located in first to third sub-pixel areas on a substrate and spaced from each other;
forming second anode electrodes on the first anode electrodes, the second anode electrodes overlapping the first anode electrodes, and electrically connected to the first anode electrodes;
forming a light emitting structure on the second anode electrodes;
forming a cathode electrode on the light emitting structure; and
forming transparent patterns between the first anode electrodes and the second anode electrodes, a thickness of the transparent patterns in at least one of the first to third sub-pixel areas being different from thicknesses of the transparent patterns in other ones of the first to third sub-pixel areas.

16. The method of claim 15, wherein the transparent patterns are formed by an inkjet process.

17. The method of claim 16, wherein the transparent patterns overlapping the first to third sub-pixel areas have different thicknesses.

18. The method of claim 16, further comprising:
forming a pixel defining layer on the first anode electrodes before the forming the second anode electrodes.

19. The method of claim 18, wherein the forming the pixel defining layer comprises:
forming openings overlapping the first anode electrodes and contact holes overlapping the first anode electrodes and spaced from the openings.

20. An electronic device, comprising:
a processor to provide input image data; and
a display device to display an image based on the input image data,
wherein the display device comprises:
a substrate;
first anode electrodes in first to third sub-pixel areas on the substrate and spaced from each other;
second anode electrodes on the first anode electrodes,
overlapping the first anode electrodes, and electrically connected to the first anode electrodes;
a light emitting structure on the second anode electrodes;
a cathode electrode on the light emitting structure; and
transparent patterns between the first anode electrodes and the second anode electrodes, wherein a thickness of the transparent patterns in at least one of the first to third sub-pixel areas is different from thicknesses of the transparent patterns in other ones of the first to third sub-pixel areas.
